(19) United States
(12) Patent Application Publication
(10) Pub. No.: US 2001/0020722 A1
(43) Pub. Date: Sep. 13, 2001

(54) Step-like silicon on isolation structure

(76) Inventor: Chien-Kuo Yang, Taipei Hsien (TW)

Correspondence Address: J.C. Patents, Inc., Suite 114, 1340 Reynolds Ave., Irvine, CA, 92614, US

(21) Appl. No.: 09/820,251

(22) Filed: Mar. 28, 2001

(30) Foreign Application Priority Data
Mar. 7, 2000 (TW) 90105287

(51) Int. Cl. H01L 29/06

(52) U.S. Cl. 257/347; 257/524

(57) ABSTRACT

A step-like silicon on isolation (SOI) structure has a substrate, wherein isolation structures are located within the substrate and an active region is located between the isolation structures; a pair of source/drain regions formed within the active region; a channel region located between the source/drain regions and within the substrate; a gate structure located on the channel region and above the substrate; and a buried insulator layer located below the source/drain regions and the channel region, wherein the buried insulator layer is substantially conformal to the source/drain regions and the channel region and has a step-like profile.

### CROSS-REFERENCE TO RELATED APPLICATION

This application claims the priority benefit of Taiwan application Ser. no. 90105287, filed Mar. 7, 2001.

### BACKGROUND OF THE INVENTION

1. Field of Invention

The present invention relates to a semiconductor device structure. More particularly, the present invention relates to semiconductor device having a step-like silicon on insulation (SOI) structure.

2. Description of Related Art

The silicon on isolation (SOI) device is a new generation semiconductor device. The substrate of the SOI structure comprises an insulator and a crystalline silicon layer formed on the insulator. Devices are then formed on the crystalline silicon layer. Comparing with metal-oxide-semiconductor (MOS) device formed on a bulky silicon substrate, the SOI-MOS device takes advantages. First, the power consumption of the SOI-MOS device is lower because the insulator below the crystalline silicon layer can prevent leakage. The threshold voltage VT is lower because the crystalline silicon layer of SOI-MOS device is very thin. Furthermore, performance of the SOI-MOS device is higher due to small parasitic capacitance of the source/drain region.

Generally, the SOI-MOS device is cataloged into two modes: one is partially depleted mode and the other is fully depleted mode. The feature of the fully depleted mode is that its crystalline silicon layer is very thin such that the crystalline silicon layer between region under the channel and the isolator fully becomes a depletion region. Comparing with the partially depleted SOI-MOS device, the fully depleted SOI-MOS device is characterized by low power consumption, low threshold voltage and high operation speed.

FIG. 1 is a cross-sectional view of a conventional SOI structure. A buried oxide (BOX) layer 12 is formed within a substrate 10. Isolation structures 14 and source/drain regions 16 are formed sequentially. A gate oxide 22 and gate 24 are then formed on the substrate 10 and between the source/drain regions 16. A spacer 20 covers the sidewall of the gate oxide 22 and the gate 24. A channel region is formed between the gate 24, the source/drain regions 16 and the buried oxide layer 12. Generally, it is necessary to form a thinner channel region.

However, according to the above SOI structure, especially for a fully depleted SOI device having a very thin channel region, if the channel region becomes thinner, the source/drain regions also becomes thinner, resulting in that resistance of the source/drain regions increases and then the driving current is restricted. Therefore, using the conventional SOI structure, it is hard to form an SOI device having a thin channel region and thick source/drain regions. Namely, a conventional SOI structure can not have features of steep subthreshold voltage, low leakage and high driving current at the same time, which is a bottleneck for developing SOI technology.

### SUMMARY OF THE INVENTION

The invention provides a step-like SOI structure, wherein the step-like SOI structure has a step-like buried insulator layer such that a thin channel region and a thick source/drain regions can exist together, which can reduce resistance of the source/drain regions to increase driving current.

As embodied and broadly described herein, the invention provides a step-like SOI structure. The step-like SOI structure comprises at least a substrate, a pair of source/drain regions, a channel region, a gate structure and a buried insulator layer. Isolation structures are located within the substrate and an active region is located between the isolation structures. The source/drain regions are formed within the active region and the channel region is located between the source/drain regions and within the substrate. The gate structure is sat on the channel region and above the substrate. And the buried insulator layer is located below the source/drain regions and the channel region, wherein the buried insulator layer is substantially conformal to the source/drain regions and the channel region and has a step-like profile.

The buried insulator layer is formed by implanting ions through the gate structure and the source/drain regions and then by an annealing process to have the step-like profile. Therefore, a thin channel region and thick source/drain regions can exist together, resulting in that the SOI transistors of the present invention have features of steep subthreshold voltage, low leakage and high driving current.

The gate structure can be a general gate structure consisting of a gate dielectric layer, a gate electrode and a spacer covering sidewalls of the gate dielectric layer and the gate electrode.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a cross-sectional view of a conventional SOI structure; and

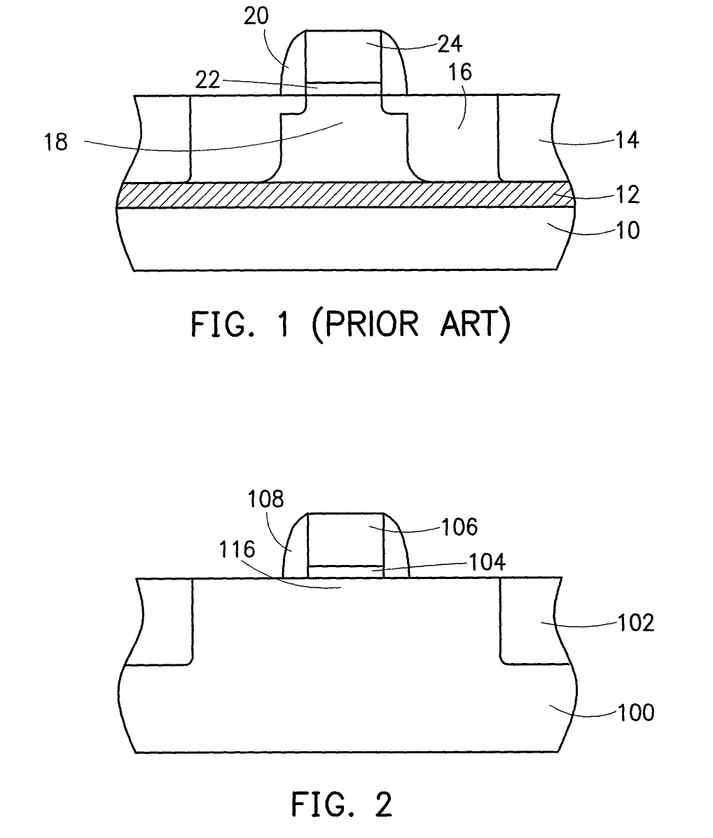

FIG. 2 through FIG. 4 schematically show cross-sectional views of the manufacturing flow chart for manufacturing devices having a step-like silicon on isolation (SOI) structure of the present invention.

### DESCRIPTION OF THE PREFERRED EMBODIMENTS

The present invention provides a step-like silicon on isolation (SOI) structure. After a gate is formed, oxygen and/or nitrogen is implanted into the substrate. Due to the existence of the gate, the implanted oxygen or nitrogen has a step-like profile below the source/drain regions within the substrate and the channel region such that a step-like buried insulator layer can be formed. Accordingly, a thin channel region and thick source/drain regions can be formed together.

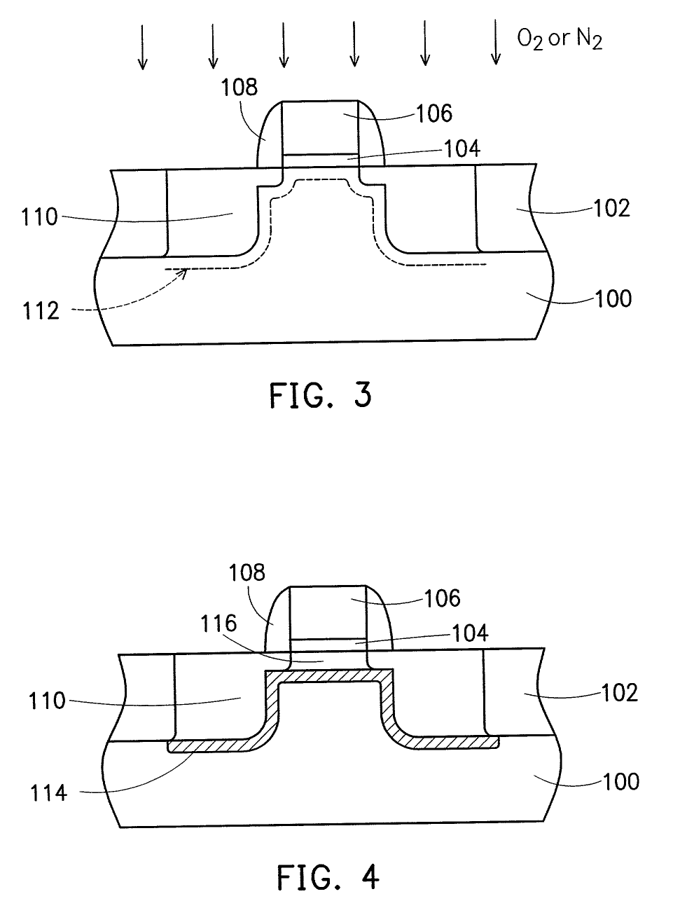

FIG. 2 through FIG. 4 schematically show cross-sectional views of the manufacturing flow chart for manufacturing devices having a step-like silicon on isolation (SOI) structure of the present invention.

Referring to FIG. 2, different from the conventional SOI structure, a buried oxide is not formed before a gate is formed. As shown in FIG. 2, a substrate 100 comprises isolation structures 102, which can be a shallow trench isolation (STI) structure or other isolation structure capable of isolating devices. Source/drain regions 110 and channel region 116 are located in an active region, which is between the isolation structures 102. The source/drain regions 110 can further comprise a light doped drain (LDD) region. Above the channel region 116, a gate structure, which for example consists of a gate dielectric layer 104 and a gate electrode 106, is sat on the substrate 100. A spacer 108 can be used to cover the sidewall of the gate structure. The gate electrode can be made of a doped polysilicon.

Referring to FIG. 3, after the gate structure is formed, oxygen and/or nitrogen ions are implanted into the substrate to a predetermined depth. As shown in FIG. 3, due to the existence of the gate structure, through the gate structure and the source/drain regions 110, the oxygen and/or nitrogen ions are implanted below the source/drain regions 110 and the channel region 116 under the gate structure. Accordingly, the implanted oxygen and/or nitrogen ions 112 have a step-like profile. Namely, the implanted oxygen and/or nitrogen ions distribute below the source/drain regions 110 and the channel region 116.

A thermal process, such as an annealing process, is performed. During the annealing process, the driven-in oxygen and/or nitrogen is bonded and reacted with silicon component of the substrate 100 to form a buried insulator layer 114. The annealing process can use laser annealing, rapid thermal process (RTP) or furnace etc. Next, the spacer 108 is removed and then an implantation process is performed to implant source/drain extension regions (the LDD regions). Finally, the spacer is reformed and then ions are implanted to form the source/drain regions 110 using the reformed spacer.

As shown in FIG. 4, the buried insulator layer 114 is located below the source/drain regions 110 and the channel region 116 and has a step-like profile, which is substantially along the source/drain regions 110 and the channel region 116. Due to the step-like buried insulator layer 114, the channel region 116 becomes thinner than the channel thickness of the conventional SOI structure. Accordingly, a thin channel region 116 and a thicker source/drain regions 110 can exist together.

According to the characteristics of the SOI structure, the thinner channel region results in a steep subthreshold voltage and a low leakage, and the thicker source/drain regions can lower the resistance and not to restrict current, resulting in a high driving current ability. Therefore, according to the step-like SOI structure of the present invention, the step-like buried insulator layer provides that an SOI-MOS transistor has a thin channel region and thick source/drain regions together. Namely, in addition to the steep subthreshold voltage and low leakage, the present invention further provides the SOI-MOS transistor having high driving current ability simultaneously.

In summary, there are at least advantages or special results as following. According to the step-like SOI structure of the present invention, the SOI structure comprises a step-like buried insulator layer such that a thin channel region and thick source/drain regions can exist together. Therefore, performance of the SOI transistors promotes and the SOI transistors of the present invention have features of steep subthreshold voltage, low leakage and high driving current.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A step-like silicon on isolation (SOI) structure, comprising:
a substrate, wherein isolation structures are located within the substrate and an active region is located between the isolation structures;
a pair of source/drain regions formed within the active region;
a channel region located between the source/drain regions and within the substrate;
a gate structure located on the channel region and above the substrate; and
a buried insulator layer located below the source/drain regions and the channel region, wherein the buried insulator layer is substantially conformal to the source/drain regions and the channel region and has a step-like profile.

2. The structure of claim 1, wherein the buried insulator layer is formed by implanting ions through the gate structure and the source/drain regions and then by an annealing process to have the step-like profile.

3. The structure of claim 1, wherein the gate structure further comprises a gate dielectric layer, a gate electrode and a spacer covering sidewalls of the gate dielectric layer and the gate electrode.

4. The structure of claim 3, further comprising a pair of light doped drain regions adjacent to the source/drain regions and below the spacer.

5. The structure of claim 2, the ions formed the buried insulator layer comprises oxygen or nitrogen ions.

6. The structure of claim 2, wherein the annealing process is selected from a group consisting of a laser annealing, a rapid thermal process and a furnace process.

7. The structure of claim 1, wherein the isolation structures comprise a shallow trench isolation (STI) structure.

8. A step-like silicon on isolation (SOI) structure, comprising:
a substrate, wherein the substrate has an active region therein, an isolation surrounds the active region and a pair of source/drain regions is located within the active region;
a gate structure located above the substrate and between the source/drain regions;
a buried insulator layer located below the source/drain regions and the gate structure, wherein the buried insulator has a step-like profile and a channel region is located within the substrate and surrounded by the source/drain regions, the gate structure and the buried insulator layer.

9. The structure of claim 8, wherein the buried insulator layer is formed by implanting ions through the gate structure and the source/drain regions and then by an annealing process to have the step-like profile.

10. The structure of claim 8, wherein the gate structure further comprises a gate dielectric layer, a gate electrode and a spacer covering sidewalls of the gate dielectric layer and the gate electrode.

11. The structure of claim 10, further comprising a pair of light doped drain regions adjacent to the source/drain regions and below the spacer.

12. The structure of claim 8, wherein the isolation structures comprise a shallow trench isolation (STI) structure.
